(19) United States
(12) Patent Application Publication
(10) Pub. No.: US 2016/0148950 A1
(43) Pub. Date: May 26, 2016

(54) THIN-FILM TRANSISTOR ARRAY SUBSTRATE, MANUFACTURING METHOD, AND DISPLAY DEVICE

(71) Applicant: Shenzhen China Star Optoelectronics Technology Co. Ltd., Shenzhen, Guangdong (CN)

(72) Inventor: Xiangyang XU, Shenzhen, Guangdong (CN)

(73) Assignee: Shenzhen China Star Optoelectronics Technology Co. Ltd., Shenzhen, Guangdong (CN)

(21) Appl. No.: 14/416,634

(22) PCT Filed: Dec. 10, 2014
(86) PCT No.: PCT/CN2014/093462

§ 371 Date: Jan. 23, 2015

(30) Foreign Application Priority Data
Nov. 20, 2014 (CN) 201410667245.X

(51) Int. Cl. H01L 27/12; G02F 1/1368; G02F 1/1362

(52) U.S. Cl. CPC H01L 27/124; H01L 27/127; G02F 1/136227; G02F 1/136209; G02F 1/1368; G02F 2001/136222

(57) ABSTRACT

A thin-film transistor array substrate includes a substrate and a plurality of thin-film transistors and a plurality of open areas formed on the substrate in a grid arrangement and also includes a first insulation protection layer, a color filter layer, a pixel electrode, a common electrode, a second insulation protection layer, a via, an insulation layer, and a black matrix arranged on the substrate. The first insulation protection layer is formed on the plurality of thin-film transistors and the plurality of open areas. The thin-film transistors each include a gate and a drain. The pixel electrode is connected through the via to the drain. The black matrix is located on the insulation layer or alternatively on the pixel electrode and the insulation layer to shield the thin-film transistors and the via. A display device and a manufacturing method of the thin-film transistor array substrate are also provided.

### CROSS REFERENCE TO RELATED APPLICATIONS

This application claims the priority of Chinese Patent Application No. 201410667245.X, entitled “Thin-Film Transistor Array Substrate, Manufacturing Method, and Display Device”, filed on Nov. 20, 2014, the disclosure of which is incorporated herein by reference in its entirety.

### BACKGROUND OF THE INVENTION

1. Field of the Invention

The present invention relates to the field of manufacture of a liquid crystal display of thin-film transistors, and in particular to a thin-film transistor array substrate, a manufacturing method of a thin-film transistor array substrate, and a display device including a thin-film transistor array substrate.

2. the Related Arts

With the progress of science and technology, liquid crystal displays are evolving in direction toward high transmittance, high resolution, and low power consumption. The higher the resolution, the smaller the size of a color filter film. When an edge length of the color filter film goes down from tens of micrometers to being just more than ten micrometers, although it is obvious that the size of the color filter has been greatly reduced, yet if the width of a black matrix of the color filter film still maintains the same, the black matrix would become too apparent for the color filter film. And, this affects the displaying performance of a display device.

Thus, an integration technique (which is referred to as Color Filter on Array, abbreviated as COA) has been proposed to integrate a color filter with an array substrate. In such a condition, a black matrix is arranged on an array substrate and reduction of width of the black matrix is made properly to ensure the black matrix is sufficient to shield those structures requiring being shielded, such as gate lines, data lines, and thin-film transistors, and to also reduce the potential chance of light leakage, so that the displaying performance of a display device can be guaranteed, while the resolution and the transmittance can also be enhanced.

However, the conventional COA black matrix is often arranged between a drain terminal of a thin-film transistor and a pixel electrode and to achieve electrical connection between the drain terminal and the pixel electrode, a via has be formed in the black matrix. Such a via affects the effect of light shielding provided by the black matrix, leading to the situation that the drain terminal may reflect light coming from an opposite side of the via thus deteriorating the displaying performance of the display device.

### SUMMARY OF THE INVENTION

The present invention provides a thin-film transistor array substrate and a manufacturing method thereof, which eliminates a drain terminal reflecting light through a via to affect the light shielding effect provided by a black matrix with respect to the drain terminal and thus increases the yield rate of the thin-film transistor array substrate and guarantees the actual performance of a display device.

The present invention also relates to a display device.

The present invention provides a thin-film transistor array substrate, which comprises a substrate and a plurality of thin-film transistors and a plurality of open areas formed on the substrate to form a grid like arrangement and further comprising a first insulation protection layer, a color filter layer, a pixel electrode, a common electrode, a second insulation protection layer, a via, an insulation layer, and a black matrix arranged on the substrate, the first insulation protection layer being formed on a plurality of thin-film transistors and a plurality of open areas, the thin-film transistors each comprising a gate and a drain, the pixel electrode being connected through the via to the drain, wherein the black matrix is located on the insulation layer or on the pixel electrode and the insulation layer to shield the thin-film transistor and the via.

In the above thin-film transistor array substrate, the color filter layer, the second insulation protection layer, the common electrode, the insulation layer, and the pixel electrode are formed to sequentially stack on the first insulation protection layer and cover the thin-film transistor and the open area, the via being arranged in an area of the color filter layer that corresponds to the drain, the pixel electrode extending into the via, the black matrix being arranged on a portion of the pixel electrode that is located in the via and a portion of the insulation layer that is located exactly above the thin-film transistor.

In the above thin-film transistor array substrate, the color filter layer, the second insulation protection layer, the pixel electrode, the insulation layer, and the common electrode are formed to sequentially stack on the first insulation protection layer and cover the thin-film transistor and the open area, the via being formed in an area of the color filter layer that corresponds to the drain, the insulation layer being formed on the pixel electrode, the pixel electrode and the insulation layer both extending into the via, the black matrix being arranged on a portion of the insulation layer a that is located in the via and a portion of the insulation layer that is located above the thin-film transistor.

In the above thin-film transistor array substrate, the thin-film transistor comprises a gate, the gate being arranged below the source and the drain, the source and the drain being respectively located on two opposite sides of the gate and partially overlapping the gate with orthogonal projections thereof, the source and the drain comprising a trench formed therebetween, the black matrix being located above the source, the drain, and the trench and covering the source, the drain, and the trench.

In the above thin-film transistor array substrate, the substrate further comprises a data line and a gate line intersecting each other, the data line and the gate line defining a thin-film transistor area in which the thin-film transistor is arranged and an open area on the substrate.

The present invention provides a display device, which comprises the above thin-film transistor array substrate.

The present invention provides a manufacturing method of a thin-film transistor array substrate. The manufacturing method comprises:

providing a substrate, on which a thin-film transistor area, an open area, and a via area are arranged;

forming a first metal layer in the thin-film transistor area of the substrate and patternizing the first metal layer to form a pattern including a gate;

forming a gate insulation layer, a semiconductor layer, and a second metal layer on a surface of the substrate on which the first metal layer is formed and the first metal layer, wherein the gate insulation layer, the semiconductor layer, and the second metal layer are sequentially stacked;

patternizing the semiconductor layer and the second metal layer to form a pattern including a source, a drain, a source transition layer, a drain transition layer, and a trench area;

forming a first insulation protection layer on the thin-film transistor and in the open area and sequentially forming a color filter layer, a second insulation protection layer, a common electrode, an insulation layer, and a pixel electrode on the first insulation protection layer, wherein a via is formed during the formation of the insulation layer and the pixel electrode is formed on the insulation layer and extends into the via; and

forming a black matrix on a portion of the pixel electrode that is located in the via and a portion of the insulation layer that is located exactly above the thin-film transistor, wherein the black matrix and the open area are adjacent to each other.

The present invention provides a manufacturing method of a thin-film transistor array substrate. The manufacturing method comprises:

providing a substrate, on which a thin-film transistor area, an open area, and a via area are arranged;

forming a first metal layer in the thin-film transistor area of the substrate and patternizing the first metal layer to form a pattern including a gate;

forming a gate insulation layer, a semiconductor layer, and a second metal layer on a surface of the substrate on which the first metal layer is formed and the first metal layer, wherein the gate insulation layer, the semiconductor layer, and the second metal layer are sequentially stacked;

patternizing the semiconductor layer and the second metal layer to form a pattern including a source, a drain, a source transition layer, a drain transition layer, and a trench area;

forming a first insulation protection layer on the thin-film transistor and in the open area and sequentially forming a color filter layer, a second insulation protection layer, a pixel electrode, an insulation layer, and a common electrode on the first insulation protection layer, wherein a via is formed during the formation of the second insulation protection layer, the insulation layer being formed on the pixel electrode, the pixel electrode and the insulation layer both extending into the via; and

forming the black matrix 18 on a portion of the insulation layer that is located in the via and a portion of the insulation layer that is located exactly above the thin-film transistor, wherein the black matrix and the open area are adjacent to each other.

In the above method, the step of forming the insulation layer further comprises a step of forming the via in an area corresponding to the drain.

In the above method, the step of forming the second insulation protection layer further comprises a step of forming the via in an area corresponding to the drain.

The present invention provides a thin-film transistor array substrate that comprises a black matrix arranged in an area exactly above a thin-film transistor and a via and is formed on a pixel electrode or a pixel electrode and an insulation layer to effectively shield reflection of surrounding light by the source and the drain at the site of the via thereby preventing the displaying performance of a display device from being affected thereby and guarantee the displaying quality of image.

### BRIEF DESCRIPTION OF THE DRAWINGS

To more clearly explain the technical solutions proposed in embodiments of the present invention or those of the prior art, a brief description of the drawings that are necessary for describing the embodiments of the present invention or the prior art is given as follows. It is obvious that the drawings that will be described below show only some embodiments of the present invention. For those having ordinary skills of the art, other drawings may also be readily available from these attached drawings without the expense of creative effort and endeavor.

FIG. 1 is a cross-sectional view showing a thin-film transistor according to a preferred embodiment of the present invention;

FIG. 2 is a cross-sectional view showing a thin-film transistor according to another preferred embodiment of the present invention;

FIG. 3 is a flow chart illustrating a manufacturing method of the thin-film transistor shown in FIG. 1; and

FIG. 4 is a flow chart illustrating a manufacturing method of the thin-film transistor shown in FIG. 2.

### DETAILED DESCRIPTION OF THE PREFERRED EMBODIMENTS

A clear and complete description will be given to technical solutions of embodiments of the present invention with reference to the attached drawings of the embodiments of the present invention. However, the embodiments so described are only some, but not all, of the embodiments of the present invention. Other embodiments that are available to those having ordinary skills of the art without the expense of creative effort and endeavor are considered belonging to the scope of protection of the present invention.

The present invention protects a thin-film transistor array substrate and a display device including the thin-film transistor array substrate. The thin-film transistor array substrate comprises a substrate and a plurality of data lines and a plurality of gate lines arranged on the substrate 1 to intersect each other (wherein the data lines and the gate lines are not shown in the drawings). The data lines and the gate lines collectively divide the substrate into a plurality of thin-film transistor areas and a plurality of open areas arranged to form a grid. Each of the thin-film transistor areas comprises one thin-film transistor arranged therein. The open areas are light transmitting areas of the display device. Illustration will be given to one of the thin-film transistors and one of the open areas of the instant embodiment.

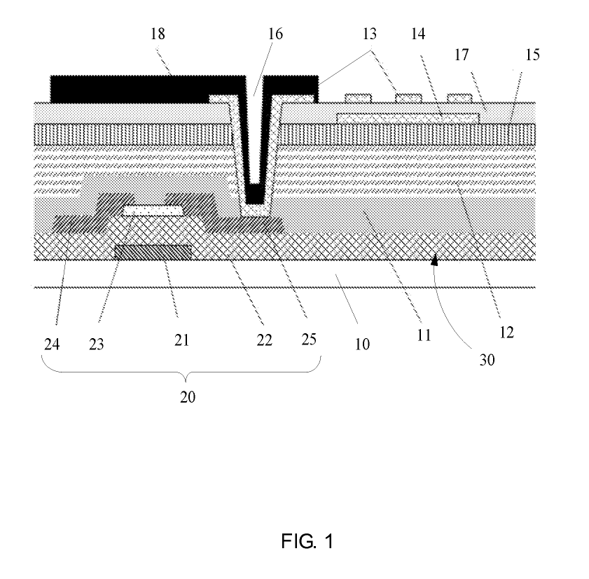

Referring to FIG. 1, the thin-film transistor array substrate further comprises a first insulation protection layer 11, a color filter layer 12, a pixel electrode 13, a common electrode 14, a second insulation protection layer 15, a via 16, an insulation layer 17, and a black matrix 18 that are arranged on the substrate 10. The first insulation protection layer 11 is formed on a plurality of thin-film transistors 20 and a plurality of open areas 30. The color filter layer 12 is formed of color photoresist materials. The color photoresist materials provide a function of light filtering and offers advantages of high color saturation and excellent light transmittance. The first insulation protection layer and the second insulation protection layer are made of silicon nitride materials.

The thin-film transistors 20 comprises a gate 21 and a gate insulation layer 22 that are sequentially stacked, an active layer 23, a source 24, and a drain 25. The pixel electrode 13 is connected through the via 16 to the drain 22. The black matrix 18 is arranged on the insulation layer 17 or on the pixel electrode 13 and the insulation layer 17 to shield the thin-film transistor 20 and the via 16. In the instant embodiment, the thin-film transistor 10 is of a bottom gate type, where the gate 21 is arranged below the source 24 and the drain 25. The source 24 and the drain 25 are respectively arranged on two opposite sides of the gate 21 and partially overlap the gate 21 in orthogonal projections thereof. A trench 26 is formed between the source 24 and the drain 25.

The color filter layer 12 comprises photoresist materials of a plurality of colors. For example, the color filter layer 12 may comprise a red photoresist material, a green photoresist material, and a blue photoresist material, or may alternatively comprise a red photoresist material, a green photoresist material, a blue photoresist material, and a yellow photoresist material, or may even comprise a transparent photoresist material or a Burgundy photoresist material. The actual color can be adjusted according to design requirements and no limitation is imposed here.

In a first embodiment of the present invention, the color filter layer 12, the second insulation protection layer 15, the common electrode 14, the insulation layer 17, and the pixel electrode 13 are formed to sequentially stack on the first insulation protection layer 11 and cover the thin-film transistor 20 and the open area 30. The via 16 is arranged in an area of the color filter layer 12 that corresponds to the drain 25. The pixel electrode 13 extends into the via 16. The black matrix 18 is arranged on the portion of the pixel electrode 13 that is located in the via 16 and the portion of the insulation layer 17 that is located exactly above the thin-film transistor. In the instant embodiment, the black matrix 18 is located above the source 24, the drain 25, and the trench 26 and covers the source 24, the drain 25, and the trench 26 and the via 16.

Specifically, in the thin-film transistor of the instant embodiment, the gate 21 is arranged on the substrate 10; the gate insulation layer 22 is arranged on the gate 21; the active layer 23 is arranged on the gate insulation layer 22; the source 24 and the drain 25 are arranged on the active layer 23; and the source 24 and the drain 25 are respectively located on two opposite sides of the gate 21 and partially overlap the gate 21 with the orthogonal projections thereof and the source 24 and the drain 25 comprises the trench 26 formed therebetween, wherein the gate 21 is connected to the gate line; the source 524 is connected to the data line; and the gate line and the data line are arranged to intersect each other. The first insulation protection layer 11 is arranged on the source 24 and the drain 25 and completely covers the trench 26 and also covers the open area 30; the color filter layer 112 is arranged on the first insulation protection layer 11; and the second insulation protection layer 15 covers the color filter layer 12. The common electrode 14 and the insulation layer 17 are sequentially formed on the second insulation protection layer 15 and then, the pixel electrode 13 is set on the insulation layer 17 and extends into the via 16. Finally, the black matrix is formed so that the black matrix 18 is located above the source 24, the drain 25, and the trench 26 and covers the source 24, the drain 25, and the trench 26 and the via 16.

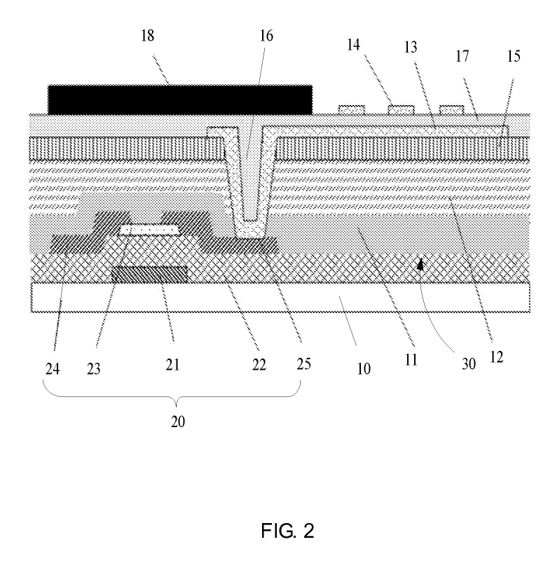

As shown in FIG. 2, in another embodiment, the color filter layer 12, the second insulation protection layer 15, the pixel electrode 13, the insulation layer 17, and the common electrode 14 are formed to sequentially stack on the first insulation protection layer 11 and cover the thin-film transistor 20 and the open area 30. The via 16 is formed in an area of the color filter layer 12 that corresponds to the drain 25. The insulation layer 17 is formed on the pixel electrode 13. The pixel electrode 13 and the insulation layer 17 both extend into the via 16. The black matrix 18 is arranged on the portion of the insulation layer 17 that is located in the via 16 and the portion of the insulation layer 17 that is located above the thin-film transistor 20.

The present invention provides a thin-film transistor array substrate that comprises a black matrix arranged in an area exactly above a thin-film transistor and a via and is formed on a pixel electrode 13 or a pixel electrode 13 and an insulation layer 17 to effectively shield reflection of surrounding light by the source 24 and the drain 25 at the site of the via 16 thereby preventing the displaying performance of a display device from being affected thereby and guarantee the displaying quality of image.

The present invention further comprises a display device including the above-described array substrate. The display device further comprises a package substrate. The package substrate and the array substrate are laminated and boxed together. The package substrate and the array substrate comprise therebetween spacers and also receive liquid crystal filled therebetween. The display device of the instant embodiment can be any product or component that includes a displaying function, such as a liquid crystal panel, an electronic paper, a mobile phone, a tablet computer, a television, a display, a notebook computer, a digital picture frame, and a navigation device.

In respect of the two embodiments described above, the present invention further provides manufacturing methods of the thin-film transistor array substrates. Before the specifics of the manufacturing methods, it is noted here that pattern formation operations may comprise only photolithographic operations or may alternatively comprise photolithographic operations and etching processes and also comprise other operations for pattern formation, including printing and ink jetting. Photolithography refers to operations for pattern formation by using photoresists, masks, and exposure machines and including film formation, exposure, and development operations. Pattern formation operations may be properly selected according to the structure to be formed in the present invention.

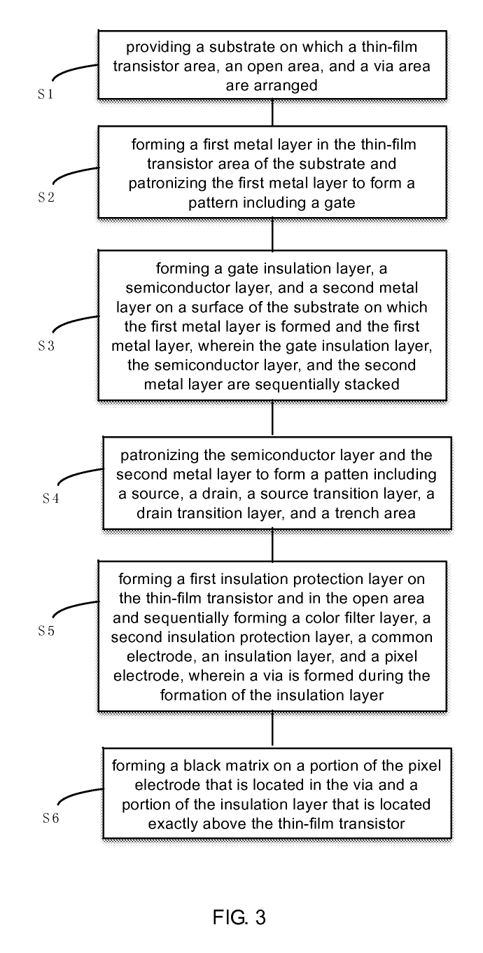

Referring to FIG. 3, for the case where the black matrix 18 is arranged on the portion of the pixel electrode 13 that is located in the via 16 and the portion of the insulation layer 17 that is located exactly above the thin-film transistor, a specific manufacturing method comprises the following steps:

Step S1: providing a substrate, on which a thin-film transistor area and an open area are arranged;

Step S2: forming a thin-film transistor in the thin-film transistor area of the substrate, wherein generally, a first metal layer is formed on the substrate and the first metal layer is patternized to form a pattern including a gate;

Step S3: forming a gate insulation layer, a semiconductor layer, and a second metal layer on a surface of the substrate on which the first metal layer is formed and the first metal layer, wherein the gate insulation layer, the semiconductor layer, and the second metal layer are sequentially stacked;

Step S4: patternizing the semiconductor layer and the second metal layer to form a pattern including a source, a drain, a source transition layer, a drain transition layer, and a trench area,

where in the above step, the sequentially stacked gate 21 and gate insulation layer 22, active layer 23, source 24, and drain 25 of the thin-film transistor 20 are formed according to the known manufacturing method of thin-film transistors and in the instant embodiment, the source and the drain comprise a-Si material or metal oxide materials and are formed through pattern formation operations; or alternatively, the source and the drain comprises poly-silicon (LTPS) material and are formed through operations of crystallization and ion injection, no constraint being imposed herein;

Step S5: forming a first insulation protection layer 11 on the thin-film transistor and in the open area and sequentially forming a color filter layer 12, a second insulation protection layer 15, a common electrode 14, an insulation layer 17, a via 16, and a pixel electrode 13 on the first insulation protection layer 11, wherein the pixel electrode 13 is formed on the insulation layer 17 and extends into the via 16,

where the step comprises Step S51: forming the first insulation protection layer 11 on the thin-film transistor 20 and in the open area 30,

Step S52: forming the color filter layer 12 on the first insulation protection layer 11 in such a way that an orthogonal projection of the color filter layer 12 is exactly cast on the source 24 and the drain 25 and the open area,

where, specifically, pattern formation operations are applied to form the color filter layer 12. Blade coating, or spin coating, or a combination of blade coating and spin coating may be adopted to first form a photoresist of one color on a surface of the thin-film transistor, followed by a photolithographic operation (including steps of exposure and development) to form a photoresist pattern corresponding to the color; then, this process is repeated until photoresist patterns of all colors are formed, this completing the formation of the color filter layer 12,

Step S53: forming the second insulation protection layer 15 and the common electrode 14 on the color filter layer 12 by applying a known operation,

Step S54: forming the insulation layer 17 on the common electrode 14, wherein in this step, the insulation layer 17 is formed on the common electrode 14 in such a way that the insulation layer 17 completely covers all the layer located below,

where, in addition, during the formation of the insulation layer 17, the via 16 is also formed in an area corresponding to the drain 25, the step being generally achieved by applying known operations, so that it is appreciated that through exposure operations, a mask is used on an area corresponding to the drain 25 where insulation is to be completely removed so as to have the insulation of the corresponding area to be completely removed after development operations thereby forming the via 16 in the insulation layer 17, and

Step S55: forming the pixel electrode 13 on the insulation layer 17, wherein in this step, pattern formation operations are applied on the insulation layer 17 to for a pattern including the pixel electrode 13, where the pixel electrode 13 is formed of indium tin oxide (ITO) and the pixel electrode 13 covers an inside wall of the via 16 and is connected to the drain 25; and

Step S6: forming a black matrix 18 on a portion of the pixel electrode 13 that is located in the via 16 and a portion of the insulation layer 17 that is located exactly above the thin-film transistor, wherein the black matrix 18 and the open area 30 are adjacent to each other. In this step, pattern formation operations are applied to form the black matrix 18, and an orthogonal projection of the black matrix 18 is exactly cast on the source 24, the drain 25, and a gate line.

In the instant embodiment, the first metal layer comprises a material selected from one of copper, tungsten, chromium, aluminum, and combinations thereof.

The gate insulation layer comprises a material selected from one of silicon oxide, silicon nitride layer, silicon oxynitride layer, and combinations thereof. The second metal layer comprises a material selected from one of copper, tungsten, chromium, aluminum, and combinations thereof. The semiconductor layer is used to form a channel for conducting on/off between the source and the drain of the thin-film transistor.

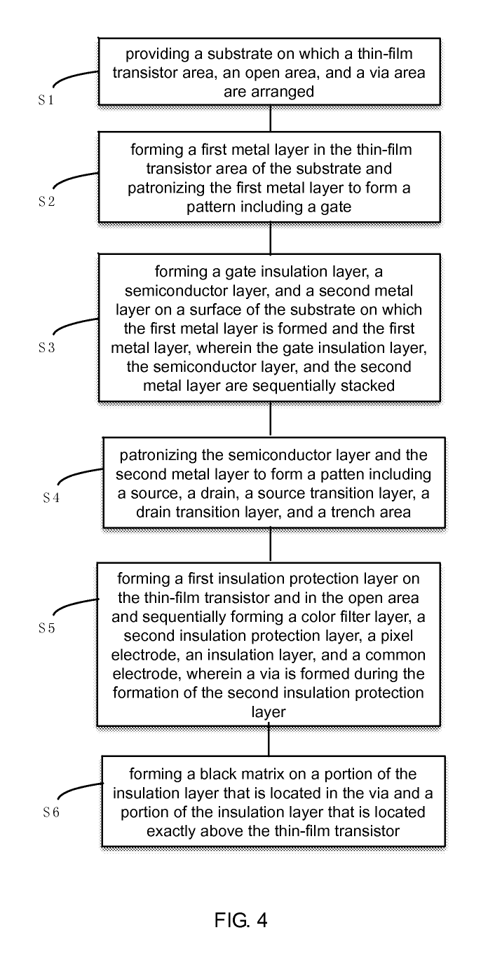

Referring to FIG. 4, for the case where the black matrix 18 is arranged on a portion of the insulation layer 17 that is located in the via 16 and a portion of the insulation layer 17 that is located exactly above the thin-film transistor 20, steps of a specific manufacturing method are similar to the previous ones, except differences residing in Step 5 and Step 6, those differences being described as follows:

In Step S5, Step S53 is performed by first forming the pixel electrode 13 and then forming the common electrode 14. A specific process of Step S43 is to apply a known operation to form the second insulation protection layer 15 and the pixel electrode 13 on the color filter layer 12.

Further, during the formation of the second insulation protection layer 15, the via 16 is also formed in an area corresponding to the drain 25. This step is generally achieved by applying known operations, so that it is appreciated that through exposure operations, a mask is used on an area corresponding to the drain 25 where insulation is to be completely removed so as to have the insulation of the corresponding area to be completely removed after development operations thereby forming the via 16 in the second insulation protection layer 15.

Step S54 is performed by applying pattern formation operations to form a pattern including the pixel electrode 13 on the second insulation protection layer 15. The pixel electrode 13 covers an inside wall of the via 16.

Step S55 is performed by forming the insulation layer 17 on the pixel electrode 13. In this step, the insulation layer 17 is formed on the pixel electrode 13 and the insulation layer 17 completely covers all the layers below and the via 16.

Step S56 is performed by forming the common electrode 14 on the insulation layer 17. In this step, pattern formation operations are applied to form a pattern including the common electrode 14 on the insulation layer 17. The common electrode 14 is formed of indium tin oxide (ITO).

Step S6 is performed by forming the black matrix 18 above the via 16 and on a portion of the insulation layer 17 located exactly above the thin-film transistor, wherein the black matrix 18 and the open area 30 are adjacent to each other. In this step, pattern formation operations are applied to form the black matrix 18, and an orthogonal projection of the black matrix 18 is exactly cast on the source 24, the drain 25, and the via 16.

Disclosed above is only one preferred embodiment of the present invention, which does not impose undue constraints to the scope of protection of the present invention. Those having ordinary skills of the art may readily appreciate that equivalent modifications that allow for realization of all or part of the operation process of the preferred embodiment described above and comply with the requirement defined in the appended claims are considered within the protection scope covered by the present invention.

What is claimed is:

1. A thin-film transistor array substrate, comprising a substrate and a plurality of thin-film transistors and a plurality of open areas formed on the substrate to form a grid like arrangement and further comprising a first insulation protection layer, a color filter layer, a pixel electrode, a common electrode, a second insulation protection layer, a via, an insulation layer, and a black matrix arranged on the substrate, the first insulation protection layer being formed on a plurality of thin-film transistors and a plurality of open areas, the thin-film transistors each comprising a gate and a drain, the pixel electrode being connected through the via to the drain, wherein the black matrix is located on the insulation layer or on the pixel electrode and the insulation layer to shield the thin-film transistor and the via.

2. The thin-film transistor array substrate as claimed in claim 1, wherein the color filter layer, the second insulation protection layer, the common electrode, the insulation layer, and the pixel electrode are formed to sequentially stack on the first insulation protection layer and cover the thin-film transistor and the open area, the via being arranged in an area of the color filter layer that corresponds to the drain, the pixel electrode extending into the via, the black matrix being arranged on a portion of the pixel electrode that is located in the via and a portion of the insulation layer that is located exactly above the thin-film transistor.

3. The thin-film transistor array substrate as claimed in claim 1, wherein the color filter layer, the second insulation protection layer, the pixel electrode, the insulation layer, and the common electrode are formed to sequentially stack on the first insulation protection layer and cover the thin-film transistor and the open area, the via being formed in an area of the color filter layer that corresponds to the drain, the insulation layer being formed on the pixel electrode, the pixel electrode and the insulation layer both extending into the via, the black matrix being arranged on a portion of the insulation layer a that is located in the via and a portion of the insulation layer that is located above the thin-film transistor.

4. The thin-film transistor array substrate as claimed in claim 2, wherein the thin-film transistor comprises a gate, the gate being arranged below the source and the drain, the source and the drain being respectively located on two opposite sides of the gate and partially overlapping the gate with orthogonal projections thereof, the source and the drain comprising a trench formed therebetween, the black matrix being located above the source, the drain, and the trench and covering the source, the drain, and the trench.

5. The thin-film transistor array substrate as claimed in claim 3, wherein the thin-film transistor comprises a gate, the gate being arranged below the source and the drain, the source and the drain being respectively located on two opposite sides of the gate and partially overlapping the gate with orthogonal projections thereof, the source and the drain comprising a trench formed therebetween, the black matrix being located above the source, the drain, and the trench and covering the source, the drain, and the trench.

6. The thin-film transistor array substrate as claimed in claim 2, wherein the substrate further comprises a data line and a gate line intersecting each other, the data line and the gate line defining a thin-film transistor area in which the thin-film transistor is arranged and an open area on the substrate.

7. The thin-film transistor array substrate as claimed in claim 3, wherein the substrate further comprises a data line and a gate line intersecting each other, the data line and the gate line defining a thin-film transistor area in which the thin-film transistor is arranged and an open area on the substrate.

8. A display device, comprising a thin-film transistor array substrate as claimed in claim 1.

9. A manufacturing method of a thin-film transistor array substrate, comprising:
providing a substrate, on which a thin-film transistor area, an open area, and a via area are arranged;
forming a first metal layer in the thin-film transistor area of the substrate and patternizing the first metal layer to form a pattern including a gate;
forming a gate insulation layer, a semiconductor layer, and a second metal layer on a surface of the substrate on which the first metal layer is formed and the first metal layer, wherein the gate insulation layer, the semiconductor layer, and the second metal layer are sequentially stacked;
patternizing the semiconductor layer and the second metal layer to form a pattern including a source, a drain, a source transition layer, a drain transition layer, and a trench area;
forming a first insulation protection layer on the thin-film transistor and in the open area and sequentially forming a color filter layer, a second insulation protection layer, a common electrode, an insulation layer, and a pixel electrode on the first insulation protection layer, wherein a via is formed during the formation of the insulation layer and the pixel electrode is formed on the insulation layer and extends into the via; and
forming a black matrix on a portion of the pixel electrode that is located in the via and a portion of the insulation layer that is located exactly above the thin-film transistor, wherein the black matrix and the open area are adjacent to each other.

10. A manufacturing method of a thin-film transistor array substrate, comprising:
providing a substrate, on which a thin-film transistor area, an open area, and a via area are arranged;
forming a first metal layer in the thin-film transistor area of the substrate and patternizing the first metal layer to form a pattern including a gate;
forming a gate insulation layer, a semiconductor layer, and a second metal layer on a surface of the substrate on which the first metal layer is formed and the first metal layer, wherein the gate insulation layer, the semiconductor layer, and the second metal layer are sequentially stacked;
patternizing the semiconductor layer and the second metal layer to form a pattern including a source, a drain, a source transition layer, a drain transition layer, and a trench area;
forming a first insulation protection layer on the thin-film transistor and in the open area and sequentially forming a color filter layer, a second insulation protection layer, a pixel electrode, an insulation layer, and a common electrode on the first insulation protection layer, wherein a via is formed during the formation of the second insulation protection layer, the insulation layer being formed on the pixel electrode, the pixel electrode and the insulation layer both extending into the via; and
forming the black matrix 18 on a portion of the insulation layer that is located in the via and a portion of the insulation layer that is located exactly above the thin-film transistor, wherein the black matrix and the open area are adjacent to each other.

11. The manufacturing method of the thin-film transistor array substrate as claimed in claim 9, wherein the step of forming the insulation layer further comprises a step of forming the via in an area corresponding to the drain.

12. The manufacturing method of the thin-film transistor array substrate as claimed in claim 10, wherein the step of forming the second insulation protection layer further comprises a step of forming the via in an area corresponding to the drain.
